(19) United States
(12) Patent Application Publication
(10) Pub. No.: US 2026/0136651 A1
(43) Pub. Date: May 14, 2026

(54) SEMICONDUCTOR DEVICES

(71) Applicant: SAMSUNG ELECTRONICS CO., LTD., Suwon-si (KR)

(72) Inventors: Panjae PARK, Suwon-si (KR); Jisoo PARK, Suwon-si (KR); Byungsung KIM, Suwon-si (KR); Kwanyoung CHUN, Suwon-si (KR)

(73) Assignee: SAMSUNG ELECTRONICS CO., LTD., Suwon-si (KR)

(21) Appl. No.: 19/206,249

(22) Filed: May 13, 2025

(30) Foreign Application Priority Data
Nov. 12, 2024 (KR) 10-2024-0160094

(51) Int. Cl. H10D 84/83; H10D 30/00; H10D 30/01; H10D 62/10; H10D 62/13; H10D 64/23; H10D 84/01

(52) U.S. Cl. CPC H10D 84/833; H10D 30/502; H10D 62/121; H10D 62/151; H10D 64/256; H10D 30/019; H10D 84/0135; H10D 84/0151

(57) ABSTRACT

A semiconductor device includes a base structure extending in a first direction; gate electrodes disposed on the base structure, extending in a second direction, and spaced apart from each other in the first direction and the second direction; a plurality of channel layers disposed on the base structure, spaced apart from each other in a third direction, and surrounded by the gate electrodes; source/drain regions connected to the plurality of channel layers on opposite sides of the gate electrodes; an isolation structure separating the gate electrodes, the plurality of channel layers, and the source/drain regions in the second direction, and extending in the first direction; and a gate connection layer electrically connecting a first gate electrode and a second gate electrode spaced apart from each other in a fourth direction, the gate connection layer disposed on the isolation structure and contacting an upper surface thereof.

### CROSS-REFERENCE TO RELATED APPLICATION

This application claims benefit of priority to Korean Patent Application No. 10-2024-0160094 filed on Nov. 12, 2024 in the Korean Intellectual Property Office, the disclosure of which is incorporated herein by reference in its entirety.

### TECHNICAL FIELD

The present disclosure relates to a semiconductor device.

### BACKGROUND

As demand for high performance, high speed, and/or multifunctionality of semiconductor devices increases, a degree of integration of semiconductor devices is increasing. In manufacturing a semiconductor device with a fine pattern corresponding to the trend for a high degree of integration of semiconductor devices, it is necessary to implement patterns having a fine width or a fine separation distance. In addition, efforts are being made to develop a semiconductor device including a transistor having a three-dimensional channel structure to overcome limitations of operating characteristics due to a decrease in the size of a planar metal oxide semiconductor FET (MOSFET).

### SUMMARY

An aspect of the present disclosure is to provide a semiconductor device having an improved degree of integration and electrical characteristics.

In some embodiments, a semiconductor device includes a base structure extending in a first direction; a plurality of gate electrodes including at least a first gate electrode and a second gate electrode disposed on the base structure and extending in a second direction, perpendicular to the first direction, the gate electrodes spaced apart from each other in the first direction and the second direction; a plurality of channel layers disposed on the base structure and spaced apart from each other in a third direction, perpendicular to the first direction and the second direction, the plurality of channel layers surrounded by the gate electrodes; source/drain regions connected to the plurality of channel layers on opposite sides of the gate electrodes; an isolation structure separating the gate electrodes, the plurality of channel layers, and the source/drain regions in the second direction, the isolation structure extending in the first direction; and a gate connection layer electrically connecting the first gate electrode and the second gate electrode, the first gate electrode and the second gate electrode spaced apart from each other in a fourth direction, intersecting the first direction and the second direction, and being perpendicular to the third direction, the gate connection layer disposed on the isolation structure and contacting an upper surface of the isolation structure.

In some embodiments, a semiconductor device includes a first gate electrode and a second gate electrode spaced apart from each other in a first direction; a third gate electrode and a fourth gate electrode spaced apart from each other in the first direction and spaced apart from the first gate electrode and the second gate electrode in a second direction, perpendicular to the first direction; an isolation structure extending in the first direction between the first gate electrode and the third gate electrode and between the second gate electrode and the fourth gate electrode; source/drain regions on opposite sides of the first gate electrode, the second gate electrode, the third gate electrode, and the fourth gate electrode in the first direction, the source/drain regions spaced apart from each other in the second direction by the isolation structure; and a gate connection layer disposed on the isolation structure, the gate connection layer having side surfaces, contacting the second gate electrode and the third gate electrode through the side surfaces on the isolation structure and electrically connecting the second gate electrode and the third gate electrode.

In some embodiments, a semiconductor device includes gate structures spaced apart from each other in a first direction and a second direction, perpendicular to the first direction, each gate structure including a gate dielectric layer, a gate electrode, and a gate capping layer sequentially stacked in a third direction perpendicular to the first direction and the second direction; a plurality of channel layers spaced apart from each other along the third direction, the plurality of channel layers surrounded by the gate structures; source/drain regions connected to the plurality of channel layers on opposite sides of the gate structure; an isolation structure separating the gate structures, the plurality of channel layers, and the source/drain regions in the second direction, the isolation structure extending in the first direction; and a gate connection layer disposed on the isolation structure, contacting the gate capping layer, and electrically connecting a first gate electrode and a second gate electrode, the first gate electrode and the second gate electrode spaced apart from each other in a fourth direction, intersecting the first direction and the second direction.

### BRIEF DESCRIPTION OF THE DRAWINGS

The above and other aspects, features, and advantages of the present disclosure will be more clearly understood from the following detailed description, taken in conjunction with the accompanying drawings, in which:

FIG. 1 is a plan view illustrating a semiconductor device according to some embodiments.

FIGS. 2A to 2C are cross-sectional views illustrating a semiconductor device according to some embodiments.

FIGS. 3A and 3B are layout views illustrating a semiconductor device according to some embodiments.

FIGS. 4A and 4B are cross-sectional views illustrating a semiconductor device according to some embodiments.

FIG. 5 is a circuit diagram of a semiconductor device according to some embodiments.

FIGS. 6A and 6B are plan views illustrating semiconductor devices according to some embodiments.

FIGS. 7A to 7D are cross-sectional views illustrating semiconductor devices according to some embodiments.

FIGS. 8A to 8G are views illustrating a process sequence illustrating a method of manufacturing a semiconductor device according to some embodiments.

### DETAILED DESCRIPTION

Hereinafter, preferred embodiments of the present disclosure will be described with reference to the attached drawings as follows. Hereinafter, terms such as ‘on,’ ‘upper,’ ‘upper portion,’ ‘upper surface,’ ‘below,’ ‘lower,’ ‘lower portion,’ ‘lower surface,’ ‘side surface,’ and the like can be understood to refer to the drawings unless otherwise explained.

The example embodiments described below may be combined with each other and described as an example embodiment.

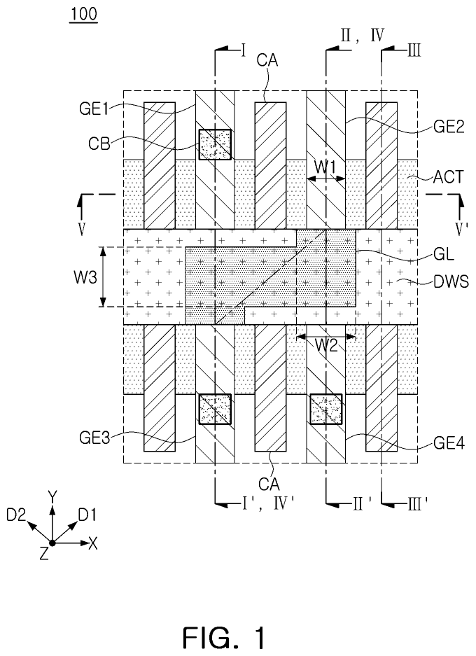

FIG. 1 is a plan view illustrating a semiconductor device according to example embodiments.

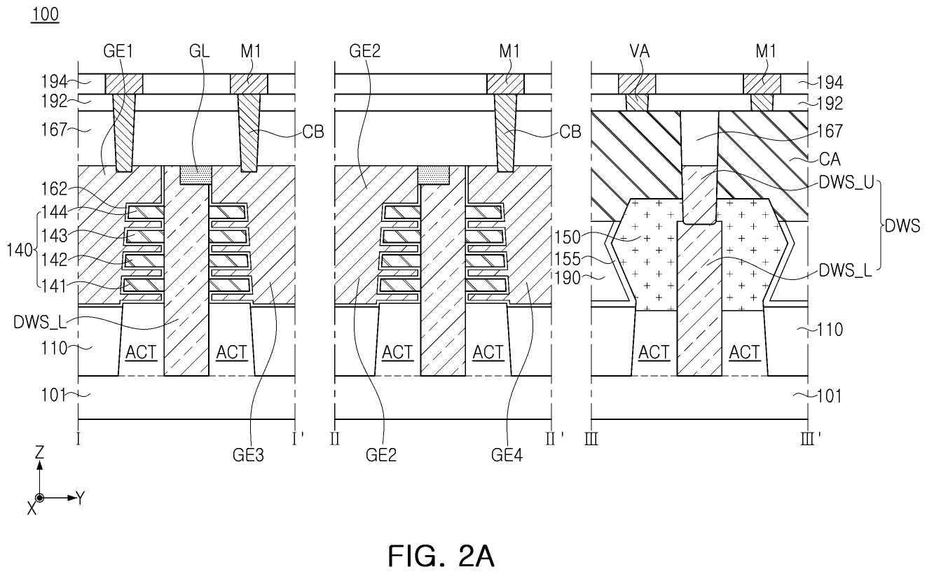

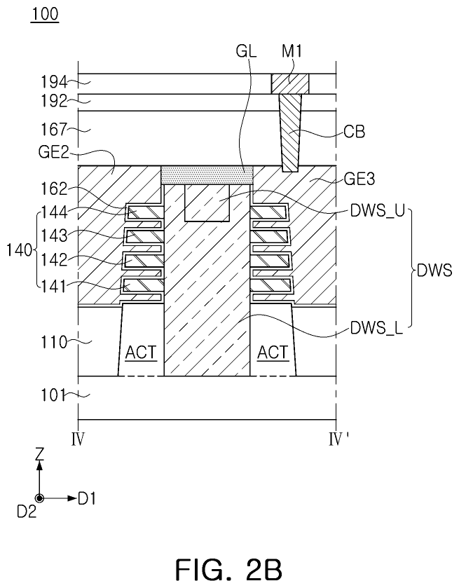

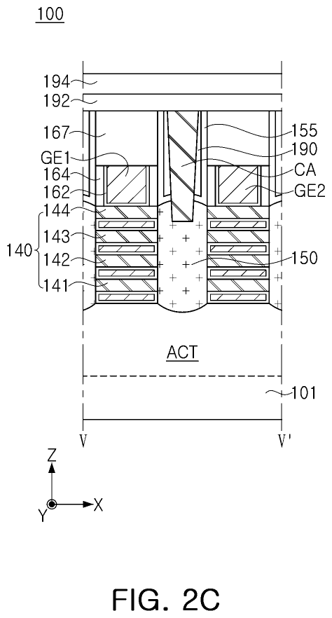

FIG. 2A illustrates a cross-section of the semiconductor device of FIG. 1, taken along lines I-I′, II-II′, and III-III′. FIG. 2B illustrates a cross-section of the semiconductor device of FIG. 1, taken along line IV-IV′. FIG. 2C illustrates a cross-section of the semiconductor device of FIG. 1, taken along line V-V′.

Referring to FIGS. 1 to 2C, a semiconductor device 100 includes active regions ACT on a substrate 101, channel structures 140 disposed vertically spaced apart from each other on the active regions ACT and including a first channel layer 141, a second channel layer 142, a third channel layer 143, and a fourth channel layer 144, a first gate electrode GE1, a second gate electrode GE2, a third gate electrode GE3, and a fourth gate electrode GE4 extending to intersect the active regions ACT, source/drain regions 150 contacting the channel structures 140, an isolation structure DWS between adjacent source/drain regions 150, a gate connection layer GL connecting the second gate electrode GE2 and the third gate electrode GE3, source contact plugs CA connected to the source/drain regions 150, and gate contact plugs CB connected to the first gate electrode GE1, the second gate electrode GE2, the third gate electrode GE3, and the fourth gate electrode GE4. The semiconductor device 100 may further include a device isolation layer 110, insulating liner layers 155, upper vias VA, first interconnection lines M1, first interlayer insulating layer 190, second interlayer insulating layer 192, and third interlayer insulating layer 194.

In the semiconductor device 100, the active regions ACT may have a fin structure or a protruding structure, and the first gate electrode GE1, the second gate electrode GE2, the third gate electrode GE3, and the fourth gate electrode GE4 may be disposed between the active regions ACT and a channel structure 140, between the first channel layer 141, the second channel layer 142, the third channel layer 143, and the fourth channel layer 144 of the channel structure 140, and on the channel structure 140. The semiconductor device 100 may include transistors having a multi-bridge channel FET (MBCFET™) structure, which may be a gate-all-around type field effect transistor.

The substrate 101 may have an upper surface extending in an X-direction and a Y-direction. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may also be provided as a bulk wafer, an epitaxial layer, a silicon-on-insulator (SOI) layer, a semiconductor-on-insulator (SeOI) layer, or the like.

The active regions ACT may be defined by the device isolation layer 110 and the isolation structure DWS on the substrate 101, and may be disposed to extend in a first direction, for example, the X-direction. The device isolation layer 110 or a lower isolation structure DWS_L of the isolation structure DWS may be disposed between adjacent active regions ACT in the Y-direction. Depending on the description, the active regions ACT may also be described as a portion of the substrate 101. In the present disclosure, the active regions ACT may also be referred to as a base structure, together with the substrate 101. The active regions ACT may partially protrude above the device isolation layer 110 below the first gate electrode GE1, the second gate electrode GE2, the third gate electrode GE3, and the fourth gate electrode GE4, and a portion of upper surfaces of the active regions ACT may be located on a level, in the vertical direction, higher than a level of an upper surface of the device isolation layer 110. The active regions ACT may be formed as a portion of the substrate 101 or may include an epitaxial layer grown from the substrate 101. The active regions ACT may be partially recessed on both sides of the first gate electrode GE1, the second gate electrode GE2, the third gate electrode GE3, and the fourth gate electrode GE4, and the source/drain regions 150 may be disposed on the recessed active regions ACT.

The active regions ACT may respectively include a well region including impurities. For example, the well region may include p-type impurities such as boron (B), gallium (Ga), or aluminum (Al), or n-type impurities such as phosphorus (P), arsenic (As), or antimony (Sb). The well region may be located at a predetermined depth in the vertical direction from the upper surface of each of the active regions ACT, for example.

The device isolation layer 110 may define the active regions ACT on the substrate 101. The device isolation layer 110 may be formed, for example, by a shallow trench isolation (STI) process. The device isolation layer 110 may expose at least the upper surfaces of the active regions ACT, and may also expose a portion of upper portions of the active regions. In some embodiments, the device isolation layer 110 may have a curved upper surface to have a higher level in the vertical direction as it approaches the active regions ACT. The device isolation layer 110 may be formed of an insulating material. The device isolation layer 110 may be, for example, an oxide, a nitride, or a combination thereof.

The first gate electrode GE1, the second gate electrode GE2, the third gate electrode GE3, and the fourth gate electrode GE4 may be disposed to extend in one direction, for example, the Y-direction, on the active regions ACT. The first gate electrode GE1, the second gate electrode GE2, the third gate electrode GE3, and the fourth gate electrode GE4 may be disposed to be spaced apart from each other in the X-direction and the Y-direction. The lower isolation structure DWS_L of the isolation structure DWS may be interposed between the first gate electrode GE1, the second gate electrode GE2, the third gate electrode GE3, and the fourth gate electrode GE4 in the Y-direction. Channel regions of transistors may be formed in the channel structures 140 intersecting the first gate electrode GE1, the second gate electrode GE2, the third gate electrode GE3, and the fourth gate electrode GE4. Each of the first gate electrode GE1, the second gate electrode GE2, the third gate electrode GE3, and the fourth gate electrode GE4 may form a gate structure, together with gate dielectric layers 162, gate spacer layers 164, and gate capping layers 167.

The gate dielectric layers 162 may be disposed between the active region ACT and the first gate electrode GE1, the second gate electrode GE2, the third gate electrode GE3, and the fourth gate electrode GE4, and between the channel structure 140 and the first gate electrode GE1, the second gate electrode GE2, the third gate electrode GE3, and the fourth gate electrode GE4. The gate dielectric layers 162 may be disposed to cover at least a portion of surfaces of the first gate electrode GE1, the second gate electrode GE2, the third gate electrode GE3, and the fourth gate electrode GE4. For example, the gate dielectric layers 162 may be disposed to surround all surfaces except for an uppermost surface of each of the first gate electrode GE1, the second gate electrode GE2, the third gate electrode GE3, and the fourth gate electrode GE4. The gate dielectric layers 162 may extend between the first gate electrode GE1, the second gate electrode GE2, the third gate electrode GE3, and the fourth gate electrode GE4 and the gate spacer layers 164, but are not limited thereto. The gate dielectric layers 162 may also extend onto a side surface of the lower isolation structure DWS_L. The gate dielectric layer 162 may include an oxide, a nitride, or a high-κ material. The high-κ material may mean a dielectric material having a higher dielectric constant than silicon oxide (SiO₂). The high-κ material may be, for example, one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), or praseodymium oxide (Pr₂O₃). In some embodiments, the gate dielectric layer 162 may be formed in a multilayer structure.

The first gate electrode GE1, the second gate electrode GE2, the third gate electrode GE3, and the fourth gate electrode GE4 may include a conductive material, for example, a metal nitride such as titanium nitride (TiN), tantalum nitride (TaN), or tungsten nitride (WN), and/or a metal material such as aluminum (Al), tungsten (W), molybdenum (Mo), or the like, or a semiconductor material such as doped polysilicon. In some embodiments, the first gate electrode GE1, the second gate electrode GE2, the third gate electrode GE3, and the fourth gate electrode GE4 may be formed in a multilayer structure. The first gate electrode GE1, the third gate electrode GE3, and the fourth gate electrode GE4 may be connected to gate contact plugs CB in an upper portion of the gate electrode.

The gate spacer layers 164 may be disposed on opposite side surfaces of each of the first gate electrode GE1, the second gate electrode GE2, the third gate electrode GE3, and the fourth gate electrode GE4 on the channel structure 140. The gate spacer layers 164 may insulate the source/drain regions 150 and the first gate electrode GE1, the second gate electrode GE2, the third gate electrode GE3, and the fourth gate electrode GE4. In some embodiments, shapes of upper ends of the gate spacer layers 164 may be variously changed, and the gate spacer layers 164 may be formed in a multilayer structure. The gate spacer layers 164 may include at least one of an oxide, a nitride, or an oxynitride, and may be formed of, for example, a low-κ film.

The gate capping layer 167 may be disposed on each of the first gate electrode GE1, the second gate electrode GE2, the third gate electrode GE3, and the fourth gate electrode GE4. In some embodiments, a lower surface of the gate capping layer 167 may have a convex shape in a downward direction. The gate capping layer 167 may include an insulating material, and may include at least one of an oxide, a nitride, or an oxynitride, for example.

The channel structures 140 may be disposed on each of the active regions ACT, in regions in which the active regions ACT intersect the first gate electrode GE1, the second gate electrode GE2, the third gate electrode GE3, and the fourth gate electrode GE4. The channel structures 140 may include the first channel layer 141, the second channel layer 142, the third channel layer 143, and the fourth channel layer 144 disposed to be spaced apart from each other in a direction perpendicular to the upper surface of each of the active regions ACT, for example, in the Z-direction. The first channel layer 141, the second channel layer 142, the third channel layer 143, and the fourth channel layer 144 may be connected to the source/drain regions 150, while being spaced apart from the upper surface of the active regions ACT in the vertical direction. The first channel layer 141, the second channel layer 142, the third channel layer 143, and the fourth channel layer 144 may have a first width, equal to or similar to a width of the active regions ACT in the Y-direction, and may have a second width, equal to or similar to a width of the gate structures in the X-direction. The first width of the first channel layer 141, the second channel layer 142, the third channel layer 143, and the fourth channel layer 144 in the Y-direction may increase toward a channel layer in a lower portion, but are not limited thereto. The number and shapes of the first channel layer 141, the second channel layer 142, the third channel layer 143, and the fourth channel layer 144 of the channel structures 140 may be variously changed in the embodiments.

The lower isolation structure DWS_L may be interposed between adjacent channel structures 140 in the Y-direction. One side surface of each of the first channel layer 141, the second channel layer 142, the third channel layer 143, and the fourth channel layer 144 in the Y-direction may be in contact with the lower isolation structure DWS_L, and may be coplanar with a side surface of the lower isolation structure DWS_L. An opposite side surface of the first channel layer 141, the second channel layer 142, the third channel layer 143, and the fourth channel layer 144 in the Y-direction may protrude into the first gate electrode GE1, the second gate electrode GE2, the third gate electrode GE3, and the fourth gate electrode GE4.

The first channel layer 141, the second channel layer 142, the third channel layer 143, and the fourth channel layer 144 may be formed of a semiconductor material, and may include, for example, at least one of silicon (Si), silicon germanium (SiGe), or germanium (Ge). The first channel layer 141, the second channel layer 142, the third channel layer 143, and the fourth channel layer 144 may be formed of, for example, the same material as the substrate 101.

The source/drain regions 150 may be disposed on opposite sides of the gate structures to be in contact with the channel structures 140. The source/drain regions 150 may be disposed to cover side surfaces of each of the first channel layer 141, the second channel layer 142, the third channel layer 143, and the fourth channel layer 144 of the channel structure 140 in the X-direction. Upper surfaces of the source/drain regions 150 may be located on a level in the vertical direction equal to or higher than lower surfaces of the first gate electrode GE1, the second gate electrode GE2, the third gate electrode GE3, and the fourth gate electrode GE4 on the channel structure 140, and the level may be variously changed in different embodiments.

The source/drain regions 150 may include an upper region having a polygonal shape in a cross-section in the Y-direction on an outer side of the gate structures. In some embodiments, a shape of the upper region is not limited to a shape illustrated in FIG. 2A, and may have a curved polygonal shape, an elliptical shape, or a circular shape. The upper region of the source/drain regions 150 may be at least covered with an insulating liner 155. In some embodiments, an insulating spacer layer may be further disposed on side surfaces of a lower region of the source/drain regions 150 in the Y-direction. The source/drain regions 150 may be respectively connected to the source contact plugs CA in an upper portion of the source/drain regions 150 in the vertical direction.

The source/drain regions 150 may include a semiconductor material, for example, at least one of silicon (Si) or germanium (Ge), and may further include impurities. Each of the source/drain regions 150 may include a plurality of epitaxial layers having different compositions.

In some embodiments, the semiconductor device 100 may further include internal spacer layers disposed between side surfaces of the source/drain regions 150 in the X-direction and the gate dielectric layers 162. The internal spacer layers may include an insulating material.

The insulating liners 155 may cover surfaces of the source/drain regions 150, and may extend over the upper surface of the device isolation layer 110 and side surfaces of the gate structures. The insulating liners 155 may include an insulating material, and may include, for example, at least one of silicon oxide, silicon nitride, or silicon oxynitride. In some embodiments, the insulating liners 155 may form a portion of the first interlayer insulating layer 190 or may be omitted.

The isolation structure DWS may have a linear shape extending in the X-direction, as illustrated in FIG. 1, and may be interposed between the first gate electrode GE1, the second gate electrode GE2, the third gate electrode GE3, and the fourth gate electrode GE4, between the active regions ACT, between the channel structures 140, and between the source/drain regions 150, in the Y-direction. The isolation structure DWS may include a lower isolation structure DWS_L and an upper isolation structure DWS_U disposed on the lower isolation structure DWS_L. The lower isolation structure DWS_L may extend continuously in the X-direction, and the upper isolation structure DWS_U may be disposed only on an outer side of the gate structures. A width of the upper isolation structure DWS_U is illustrated in FIG. 2A as being smaller than a width of the lower isolation structure DWS_L, but is not limited thereto, and may be equal to or greater than the width of the lower isolation structure DWS_L.

An upper surface of the lower isolation structure DWS_L may be located on a level in the vertical direction substantially equal to upper surfaces of the first gate electrode GE1, the second gate electrode GE2, the third gate electrode GE3, and the fourth gate electrode GE4 between the gate structures. In some embodiments, the upper surface of the lower isolation structure DWS_L may be located on a level in the vertical direction equal or similar to the upper surface of the fourth channel layer 144 in an uppermost portion. In this case, a separate gate isolation structure may be further disposed on the lower isolation structure DWS_L to separate the first gate electrode GE1, the second gate electrode GE2, the third gate electrode GE3, and the fourth gate electrode GE4. The lower isolation structure DWS_L may have an inclined side surface having a width that decreases along the vertical direction toward the substrate 101, but a shape of the side surface of the lower isolation structure DWS_L is not limited thereto.

The lower isolation structure DWS_L may be disposed at a relatively small height on the outside of the gate structures. Therefore, the upper surface of the lower isolation structure DWS_L may be located on a relatively low level in the vertical direction and may be located at a level in the vertical direction lower than an upper surface of the source/drain region 150.

The upper isolation structure DWS_U may be disposed between the source/drain regions 150 in the Y direction on the outside of the gate structures, and may be connected to the lower isolation structure DWS_L. The upper isolation structure DWS_U may extend vertically between adjacent source contact plugs CA in the Y-direction. An upper surface of the upper isolation structure DWS_U may be located on a level in the vertical direction lower than a level of upper surfaces of the source contact plugs CA. For example, the upper surface of the upper isolation structure DWS_U may be located on a level in the vertical direction substantially equal to a lower surface of the gate capping layer 167, and may be located on a level in the vertical direction substantially equal to the upper surface of the lower isolation structure DWS_L between the gate structures. For example, the height of the isolation structure DWS may be constant. The upper isolation structure DWS_U may be disposed in a form in which a portion including an upper region is removed in a region in which the gate connection layer GL is disposed.

The isolation structure DWS may include an insulating material, and may include, for example, a different material from the device isolation layer 110. The isolation structure DWS may include, for example, at least one of silicon nitride or silicon oxynitride. For example, the lower isolation structure DWS_L and the upper isolation structure DWS_U may include the same material.

The gate connection layer GL may physically and electrically connect the second gate electrode GE2 and the third gate electrode GE3, which may be gate electrodes spaced apart from each other in a diagonal direction, for example, in a D1-direction. The D1-direction may intersect the X-direction and the Y-direction, and may be a direction parallel to the upper surface of the substrate 101. The gate connection layer GL may be spaced apart from the first gate electrode GE1 and the fourth gate electrode GE4, for example, in the Y-direction. The first gate electrode GE1 and the fourth gate electrode GE4 may or may not be electrically connected to each other. When electrically connected to each other, the first gate electrode GE1 and the fourth gate electrode GE4 may be connected through an interconnection structure in an upper portion, not illustrated in FIG. 1.

The gate connection layer GL may have a shape in which lines or patterns extending in the X-direction and the Y-direction are connected, and may extend in the D1-direction as a whole. For example, the gate connection layer GL may include patterns extending in the Y-direction, and a pattern connecting the same and extending in the X-direction. In the gate connection layer GL, a second width W2 of patterns connecting the second gate electrode GE2 and the third gate electrode GE3 and extending in the Y-direction may be greater than a first width W1 of the second gate electrode GE2 and the third gate electrode GE3. In the gate connection layer GL, a third width W3 of the patterns connecting the patterns extending in the Y-direction and extending in the X-direction may be greater than the second width W2, but is not limited thereto. A maximum width of the gate connection layer GL, for example, the third width W3, may be smaller than a width of the isolation structure DWS. In the present disclosure, unless otherwise stated, the term ‘width’ may refer to a length in a direction, perpendicular to the extension direction.

The gate connection layer GL may entirely overlap the isolation structure DWS in the plan view of FIG. 1. The gate connection layer GL may entirely overlap the isolation structure DWS in the Z-direction. As illustrated in FIGS. 2A and 2B, the gate connection layer GL may be disposed on the isolation structure DWS in a state in which a portion of the isolation structure DWS is removed. For example, the gate connection layer GL may be disposed, with the lower isolation structure DWS_L recessed from an upper surface to a predetermined depth, in regions along a straight line with the second gate electrode GE2 and the third gate electrode GE3 in the Y-direction. The gate connection layer GL may be disposed, with the upper isolation structure DWS_U recessed from an upper surface to a predetermined depth, outside the regions along the straight line. The gate connection layer GL may also be disposed in a state in which a portion of an adjacent gate dielectric layer 162 is removed.

A portion of a first side surface of the gate connection layer GL may be in contact with side surfaces of the second gate electrode GE2 and the third gate electrode GE3, and a portion of a second side surface, opposite the first side surface, may be in contact with the isolation structure DWS. An upper surface of the gate connection layer GL may be coplanar with upper surfaces of the second gate electrode GE2 and the third gate electrode GE3 and an upper surface of the lower isolation structure DWS_L, but a level of the upper surface of the gate connection layer GL may not be limited thereto. The upper surface of the gate connection layer GL may be entirely covered with the gate capping layer 167. In some embodiments, the gate contact plug CB may also be disposed on the gate connection layer GL. The lower surface of the gate connection layer GL may be located on a level in the vertical direction lower than the upper surfaces of the second gate electrode GE2 and the third gate electrode GE3 and higher than the lower surfaces of the second gate electrode GE2 and the third gate electrode GE3. The entire lower surface of the gate connection layer GL may be covered with the lower isolation structure DWS_L and the gate dielectric layer 162.

A thickness of the gate connection layer GL may be smaller than a thickness of the second gate electrode GE2 and the third gate electrode GE3 on the uppermost channel layer 144. The gate connection layer GL may be located on a level corresponding to a portion of the second gate electrode GE2 and the third gate electrode GE3.

The gate connection layer GL may include a conductive material, and may include, for example, aluminum (Al), tungsten (W), or molybdenum (Mo). The gate connection layer GL may include the same material as or a different material from the first gate electrode GE1, the second gate electrode GE2, the third gate electrode GE3, and the fourth gate electrode GE4. For example, the first gate electrode GE1, the second gate electrode GE2, the third gate electrode GE3, and the fourth gate electrode GE4 may include tungsten (W), and the gate connection layer GL may include molybdenum (Mo). In some embodiments, the gate connection layer GL may further include a barrier layer forming a lower surface and side surfaces.

The semiconductor device 100 may include the gate connection layer GL connecting gate electrodes in a diagonal direction to simplify an interconnection structure, thereby facilitating a manufacturing process, and may reduce coupling capacitance and routing resistance, as compared to a case of connecting gate electrodes through an interconnection structure in an upper portion of the semiconductor device.

The first interlayer insulating layer 190 may cover the source/drain regions 150. The second interlayer insulating layer 192 may cover the gate structures and the source contact plugs CA. The third interlayer insulating layer 194 may be disposed on the second interlayer insulating layer 192. The first interlayer insulating layer 190, the second interlayer insulating layer 192, and the third interlayer insulating layer 194 may include an insulating material, such as at least one of an oxide, a nitride, or an oxynitride, and may include, for example, a low-κ material. In some embodiments, at least one of the first interlayer insulating layer 190, the second interlayer insulating layer 192, and the third interlayer insulating layer 194 may include a plurality of insulating layers.

The source contact plugs CA may be connected to the upper region of the source/drain regions 150, and may apply an electrical signal to the source/drain regions 150. The source contact plugs CA may penetrate the first interlayer insulating layer 190 and the insulating liners 155. The source contact plugs CA may have an inclined side surface in which a width of a lower portion is less than a width of an upper portion, depending on an aspect ratio, but are not limited thereto. The source contact plugs CA may be disposed by recessing the source/drain regions 150 from upper surfaces. The source contact plugs CA may extend in the vertical direction from the upper portion toward, for example, below the lower surface of the fourth channel layer 144 in an uppermost portion of the channel structure 140, but are not limited thereto.

The gate contact plugs CB may be connected to the first gate electrode GE1, the third gate electrode GE3, and the fourth gate electrode GE4 by penetrating the second interlayer insulating layer 192 and the gate capping layer 167. Since the second gate electrode GE2 and the third gate electrode GE3 are directly connected by the gate connection layer GL, the gate contact plug CB does not need to be connected to both the second gate electrode GE2 and the third gate electrode GE3, and may be connected to either one thereof.

The source contact plugs CA and the gate contact plugs CB may include a conductive material, for example, a metal material such as aluminum (Al), tungsten (W), molybdenum (Mo), or the like. In some embodiments, the source contact plug CA may include a metal-semiconductor compound layer, such as a metal silicide layer, located at an interface with the source/drain region 150, and may further include a barrier layer forming side surfaces of the source contact plug CA and extending onto an upper surface of the metal-semiconductor compound layer. Similarly, the gate contact plug CB may include a metal-semiconductor compound layer, such as a metal silicide layer, located at an interface with the first gate electrode GE1, the third gate electrode GE3, and the fourth gate electrode GE4, and may further include a barrier layer forming side surfaces of the gate contact plug CB and extending onto an upper surface of the metal-semiconductor compound layer. The barrier layer may include, for example, a metal nitride, such as titanium nitride (TiN), tantalum nitride (TaN), or tungsten nitride (WN).

The upper vias VA may electrically connect the source contact plugs CA and the first interconnection lines M1. The upper vias VA and the first interconnection lines M1 may include a conductive material, for example, at least one of tungsten (W), copper (Cu), aluminum (Al), cobalt (Co), ruthenium (Ru), titanium (Ti), or molybdenum (Mo). Additional vias and interconnection lines may be further disposed on the upper vias VA and the first interconnection lines M1. In some embodiments, the connection forms of the gate contact plugs CB, the source contact plugs CA, the upper vias VA, and the first interconnection lines M1 may be variously changed.

In description of embodiments below, any description overlapping the description above with reference to FIGS. 1 to 2C will be omitted.

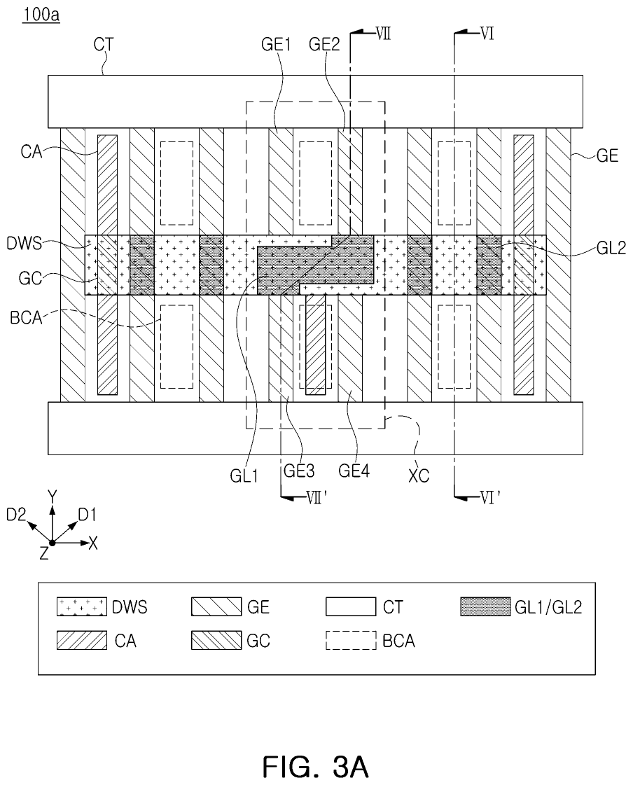

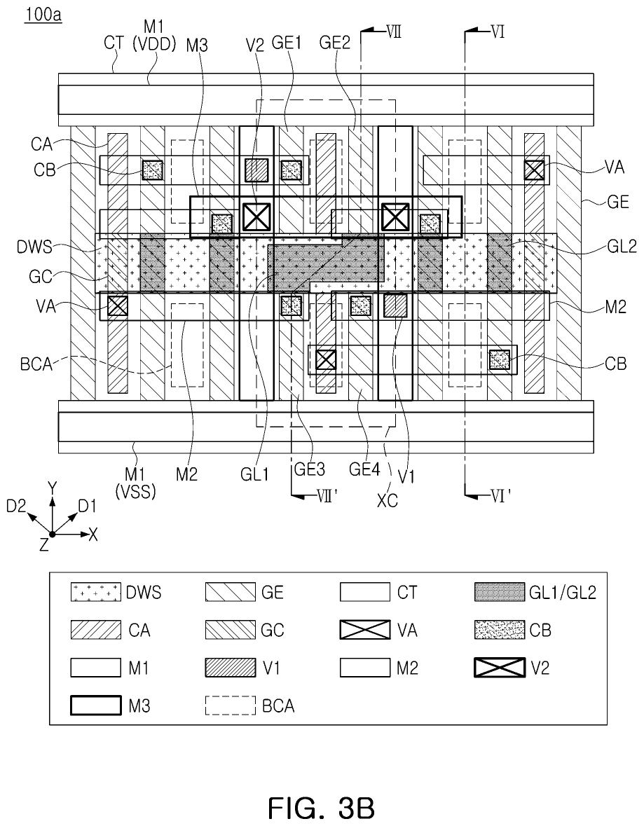

FIG. 3B further illustrates some components forming an interconnection structure in the layout view of FIG. 3A.

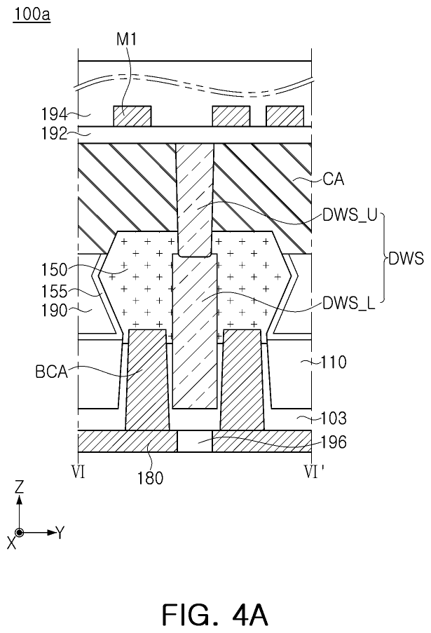

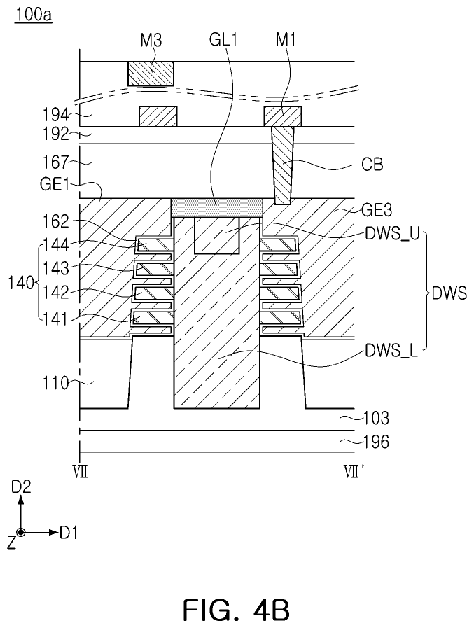

FIGS. 4A and 4B illustrate cross-sections of the semiconductor device of FIGS. 3A and 3B, taken along lines VI-VI′ and VII-VII′.

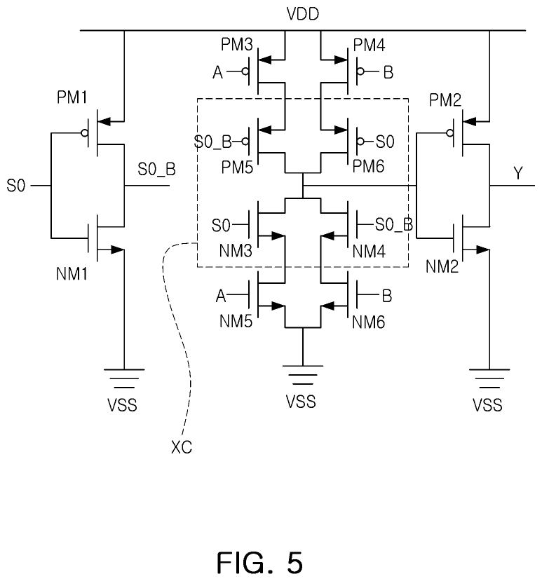

Referring to FIGS. 3A to 5, a semiconductor device 100a may include a standard cell of a multiplexer (MUX) circuit of FIG. 5. As illustrated in FIG. 5, the semiconductor device 100a may include first NMOS transistor NM1, second NMOS transistor NM2, third NMOS transistor NM3, fourth NMOS transistor NM4, fifth NMOS transistor NM5, and sixth NMOS transistor NM6 and first PMOS transistor PM1, second PMOS transistor PM2, third PMOS transistor PM3, fourth PMOS transistor PM4, fifth PMOS transistor PM5, and sixth PMOS transistors PM6. The first NMOS transistor NM1 and the first PMOS transistor PM1 may configure an inverter, may receive a select signal S0 through a gate electrode, and may output a complementary select signal S0_B. The third PMOS transistor PM3 and the fifth NMOS transistor NM5 may receive a first select signal A through a gate electrode, and the fourth PMOS transistor PM4 and the sixth NMOS transistor NM6 may receive a second select signal B through a gate electrode. The fifth PMOS transistor PM5 and the sixth PMOS transistor PM6 and the third NMOS transistor NM3 and the fourth NMOS transistor NM4 may form a cross couple circuit XC, and source/drain regions thereof may be connected to each other with the third PMOS transistor PM3 and the fourth PMOS transistor PM4 and the fifth NMOS transistor NM5 and the sixth NMOS transistor NM6, respectively. The second NMOS transistor NM2 and the second PMOS transistor PM2 may form an inverter, may receive a signal from the cross couple circuit XC to a gate electrode, and may output one of the first select signal A and the second select signal B as an output signal Y.

Unlike the embodiments of FIGS. 1 to 2C, the semiconductor device 100a may not include a substrate 101 and active regions ACT, but may further include a substrate insulating layer 103, a back surface insulating layer 196, second gate connection layers GL2, backside contact plugs BCA, and backside interconnection lines 180. The semiconductor device 100a may further include a gate isolation layer CT, a contact connection layer GC, first via V1, second via V2, second interconnection line M2, and third interconnection line M3.

The substrate insulating layer 103 may be a layer formed by removing and/or oxidizing the active regions ACT and the substrate 101 formed of a semiconductor material during a manufacturing process. In the present disclosure, the substrate insulating layer 103 may also be referred to as a base structure. The back surface insulating layer 196 may be disposed on a lower surface of the substrate insulating layer 103. The substrate insulating layer 103 and the back surface insulating layer 196 may be formed of an insulating material, and may include, for example, an oxide, a nitride, or a combination thereof. In some embodiments, at least one of the substrate insulating layer 103 or the back surface insulating layer 196 may include a plurality of insulating layers.

A first gate connection layer GL1 may electrically connect second gate electrode GE2 and third gate electrode GE3 to each other, and the description of the gate connection layer GL described above with reference to FIGS. 1 to 2C may be equally applied thereto. The second gate connection layer GL2 may connect adjacent gate electrodes GE in the Y-direction in a straight line from the gate electrodes GE, as illustrated in FIGS. 3A and 3B. The second gate connection layer GL2 may connect the gate electrodes GE outside the first gate electrode GE1, the second gate electrode GE2, the third gate electrode GE3, and the fourth gate electrode GE4 to each other in the Y-direction. The second gate connection layer GL2 may be formed, together with the first gate connection layer GL1, to be disposed on an isolation structure DWS on a level in the vertical direction equal to a level of the first gate connection layer GL1, and may include the same material as the first gate connection layer GL1.

Backside contact plugs BCA may penetrate the substrate insulating layer 103 and be connected to a lower surface of at least one of the source/drain regions 150. The backside contact plugs BCA may be disposed by partially recessing a source/drain region 150 from a lower surface. Backside interconnection lines 180 may be disposed in the back surface insulating layer 196 to be connected to the backside contact plugs BCA. In some embodiments, additional contact plugs and interconnection lines may be further disposed between the backside contact plugs BCA and the backside interconnection lines 180. The backside interconnection lines 180, together with the backside contact plugs BCA, may form a backside power delivery network (BSPDN) applying power or ground voltage. For example, power and ground signals may be respectively delivered to the backside contact plugs BCA of FIG. 4A, and power and ground signals may also be respectively delivered to the backside contact plugs BCA disposed symmetrically on a left side in FIGS. 3A and 3B. The backside contact plugs BCA between the first gate electrode GE1, the second gate electrode GE2, the third gate electrode GE3, and the fourth gate electrode GE4 forming the cross couple circuit XC may be electrically connected to each other.

The backside contact plugs BCA and the backside interconnection lines 180 may include a conductive material, for example, a metal material such as aluminum (Al), tungsten (W), molybdenum (Mo), or the like.

The gate isolation layer CT may be disposed at both ends of the standard cell in the Y-direction to separate the gate electrodes GE. The gate isolation layer CT may include an insulating material, and unlike the isolation structure DWS, may be disposed in end portions of the standard cell to separate only the gate electrodes GE or the gate structures between the standard cells in the Y-direction.

The contact connection layer GC may connect adjacent source contact plugs CA in the Y-direction to each other. The contact connection layer GC may be disposed on the isolation structure DWS, and may include a conductive material. The first vias V1 may connect first interconnection lines M1 and the second interconnection lines M2, and the second vias V2 may connect the second interconnection lines M2 and the third interconnection lines M3. The first via V1, the second via V2, the second interconnection line M2, and the third interconnection line M3 may include a conductive material, and may include, for example, a metal material.

The fifth PMOS transistor PM5, the sixth PMOS transistor PM6, the third NMOS transistor NM3, and the fourth NMOS transistor NM4 forming the cross couple circuit XC may include the first gate electrode GE1, the second gate electrode GE2, the third gate electrode GE3, and the fourth gate electrode GE4, respectively. The second gate electrode GE2 and the third gate electrode GE3 may be directly connected through the first gate connection layer GL1, and the first gate electrode GE1 and the fourth gate electrode GE4 may be electrically connected to each other through interconnection structures. Specifically, as illustrated in FIG. 3B, the first gate electrode GE1 may be electrically connected to the fourth gate electrode GE4 through a gate contact plug CB, a first interconnection line M1, a first via V1, a second interconnection line M2, a second via V2, a third interconnection line M3, a second via V2, a second interconnection line M2, a first via V1, a first interconnection line M1, and a gate contact plug CB.

The semiconductor device 100a may have a structure in which connection of the second gate electrode GE2 and the third gate electrode GE3 is simplified, unlike the connection of first gate electrode GE1 and the fourth gate electrode GE4. The semiconductor device 100a may form the cross couple circuit XC in contacted poly pitch (CPP) corresponding to a pitch of two gate electrodes, and by including a first gate connection layer GL1 connecting the gate electrodes in a diagonal direction, an interconnection structure may be simplified, simplifying manufacturing, and coupling capacitance and routing resistance may be reduced. A structure of the first gate connection layer GL1 may be applied to various circuits including a cross couple structure, such as a flip-flop circuit or the like, in addition to a multiplexer (MUX).

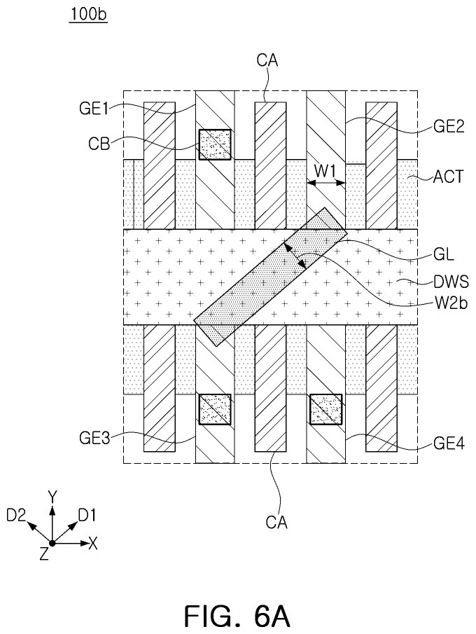

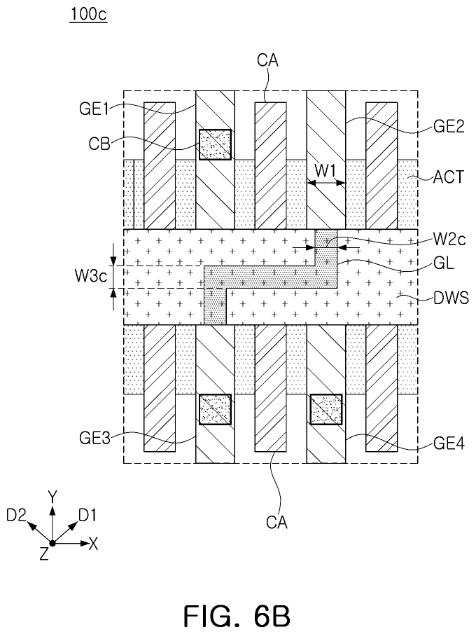

FIG. 6A and FIG. 6B illustrate regions corresponding to FIG. 1, respectively.

Referring to FIG. 6A, in a semiconductor device 100b, a gate connection layer GL may include a line pattern connecting a second gate electrode GE2 and a third gate electrode GE3 and extending in the D1-direction. A second width W2b of the gate connection layer GL may be equal to or similar to a first width W1 of the second gate electrode GE2 and the third gate electrode GE3, but is not limited thereto, and may be variously changed in different embodiments.

In the gate connection layer GL, at least a portion including a central region in the X-direction and the Y-direction may overlap with an isolation structure DWS in a plan view. A portion of the gate connection layer GL may not overlap the isolation structure DWS, and may be located outside the isolation structure DWS. The gate connection layer GL may be disposed such that a portion overlaps the second gate electrode GE2 and the third gate electrode GE3 in a plan view. In this case, the second gate electrode GE2 and the third gate electrode GE3 may be disposed in a partially recessed form. In some embodiments, the gate connection layer GL may not be disposed in a region overlapping the second gate electrode GE2 and the third gate electrode GE3.

Referring to FIG. 6B, in a semiconductor device 100c, a gate connection layer GL may include a plurality of line patterns connecting a second gate electrode GE2 and a third gate electrode GE3 in the D1-direction. Unlike the embodiment of FIG. 1, in the gate connection layer GL shown in FIG. 6B, a second width W2c of patterns connecting the second gate electrode GE2 and the third gate electrode GE3 and extending in the Y-direction may be smaller than a first width W1 of the second gate electrode GE2 and the third gate electrode GE3. In the gate connection layer GL, a third width W3c of a pattern connecting the patterns extending in the Y-direction and extending in the X-direction may be equal or similar to the second width W2c, but may not be limited thereto.

As in the embodiments of FIGS. 6A and 6B, a shape, a width, and an arrangement range of the gate connection layer GL on the plan view may be variously changed in different embodiments.

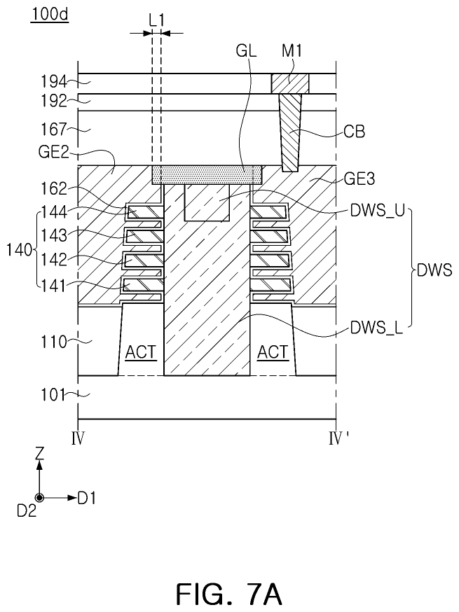

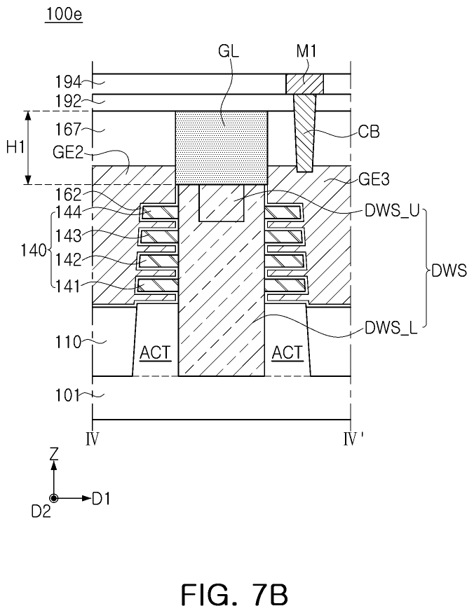

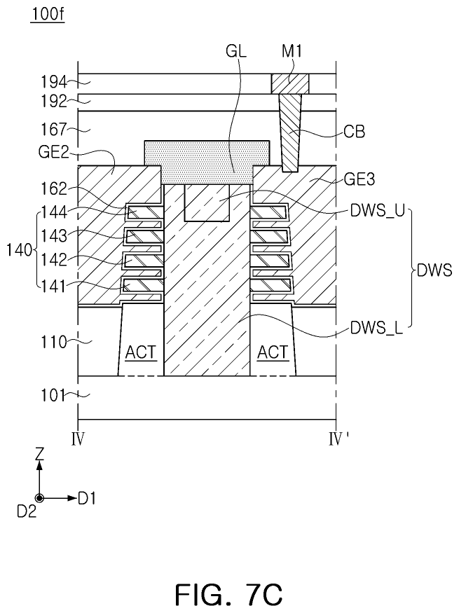

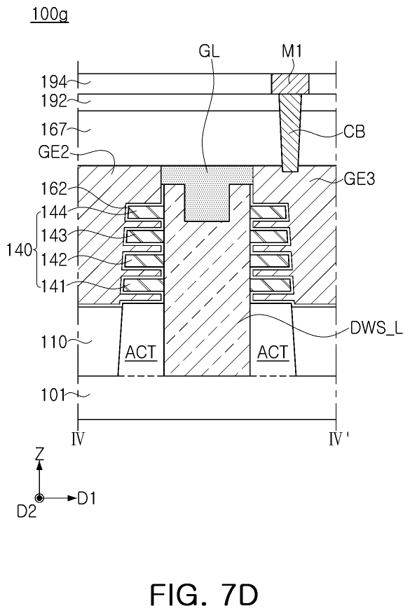

FIGS. 7A to 7D illustrate regions corresponding to FIG. 2B, respectively.

Referring to FIG. 7A, in a semiconductor device 100d, a gate connection layer GL may have a shape extending horizontally toward at least one of second gate electrode GE2 or third gate electrode GE3 with a first length L1. Therefore, the gate connection layer GL may protrude into the second gate electrode GE2 and the third gate electrode GE3. The first length L1 may be changed in different embodiments.

Referring to FIG. 7B, in a semiconductor device 100e, a gate connection layer GL may extend upwardly in the vertical direction through a gate capping layer 167. Therefore, an upper surface of the gate connection layer GL may be located on a level in the vertical direction higher than a level of upper surfaces of second gate electrode GE2 and the third gate electrode GE3. The upper surface of the gate connection layer GL may be coplanar with an upper surface of the gate capping layer 167. In this case, the upper surface of the gate connection layer GL may be located on a level in the vertical direction lower than a level of an upper surface of a gate contact plug CB. The gate connection layer GL shown in FIG. 7B may be formed after the gate capping layer 167 is formed. An upper surface of an upper isolation structure DWS_U (see FIG. 2A) may be located on a same level in the vertical direction as the upper surface of the gate capping layer 167.

In some embodiments, a height H1 of the gate connection layer GL may be variously changed, as the level of the upper surface of the gate connection layer GL in the vertical direction is changed within a range, equal to or lower than the level of the upper surface of the gate capping layer 167. In some embodiments, the gate connection layer GL may be in contact with or integral with the gate contact plug CB connected to the second gate electrode GE2 and the third gate electrode GE3.

Referring to FIG. 7C, in a semiconductor device 100f, a gate connection layer GL may be disposed to extend in the vertical direction from an upper surface of an isolation structure DWS to upper surfaces of second gate electrode GE2 and third gate electrode GE3 while protruding into the gate capping layer 167. Therefore, the gate connection layer GL may also be in contact with the upper surfaces of the second gate electrode GE2 and the third gate electrode GE3.

Referring to FIG. 7D, in a semiconductor device 100g, an upper isolation structure DWS_U (see FIG. 2A) may not be disposed below a gate connection layer GL in the vertical direction. The gate connection layer GL may include a region protruding downward in the vertical direction from a central region in the D1-direction, according to a level of an upper surface of a lower isolation structure DWS_L. In the embodiment shown in FIG. 7D, the semiconductor device 100g may be manufactured by not forming the upper isolation structure DWS_U in a region in which the gate connection layer GL is disposed.

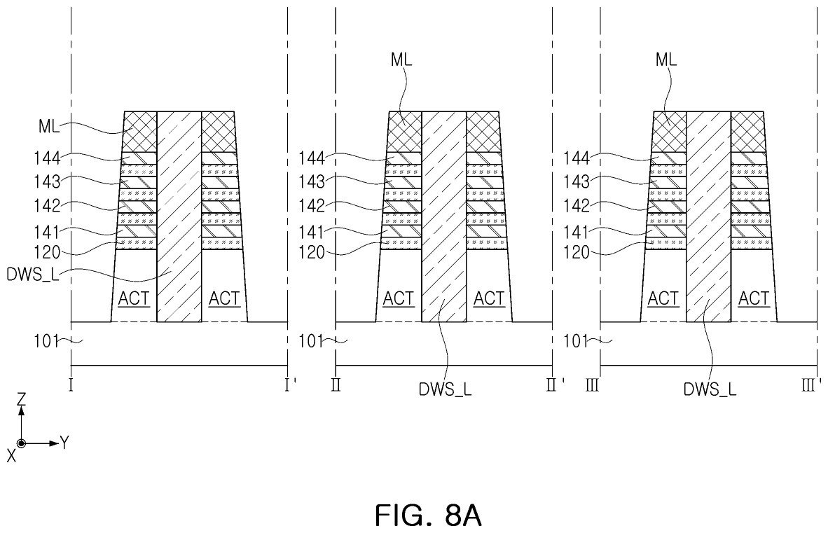

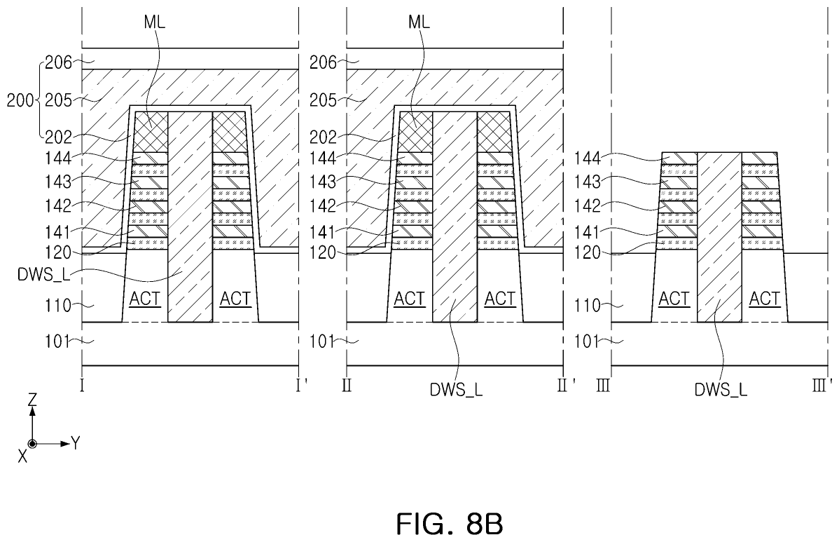

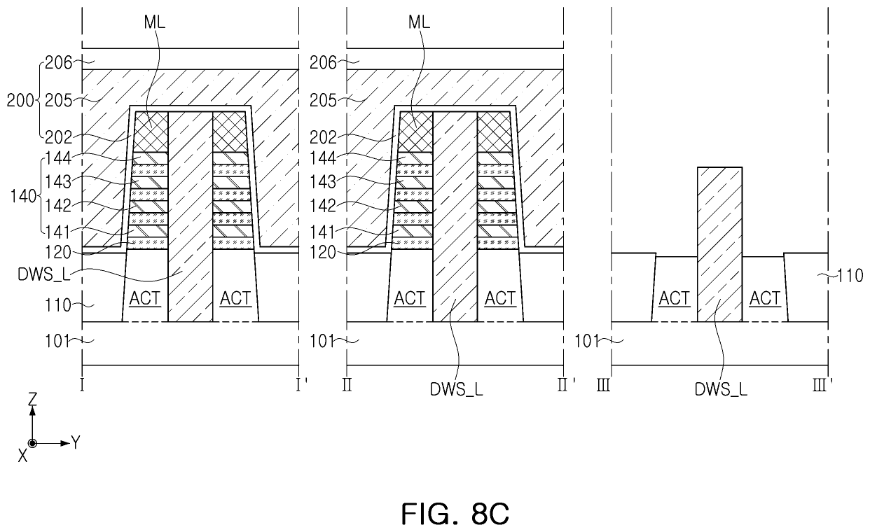

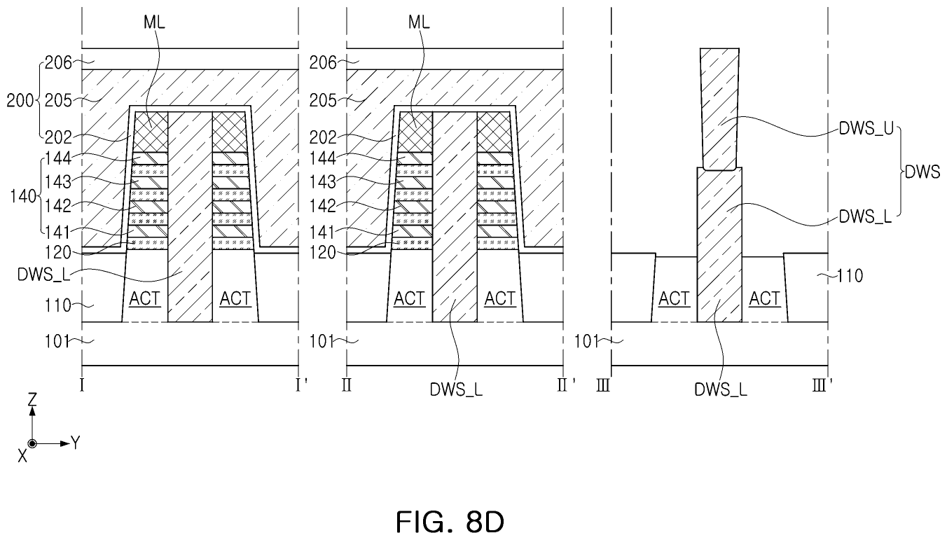

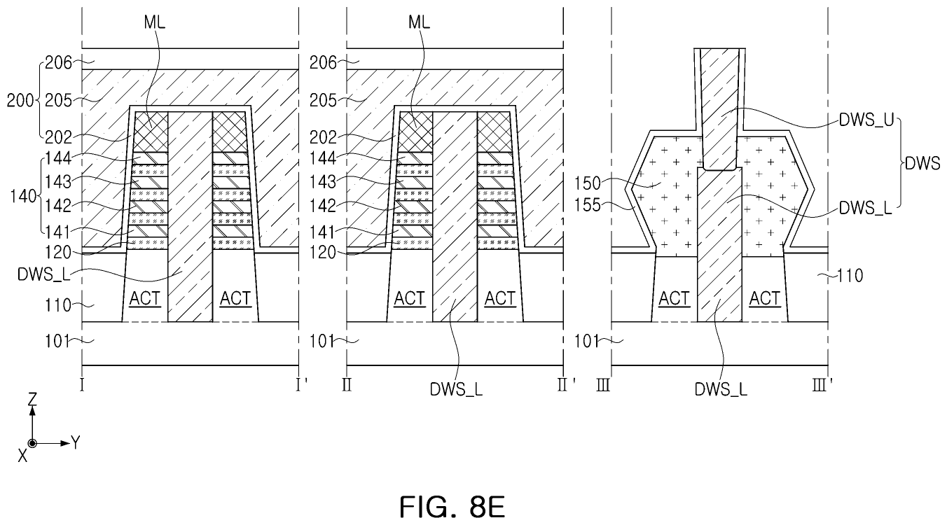

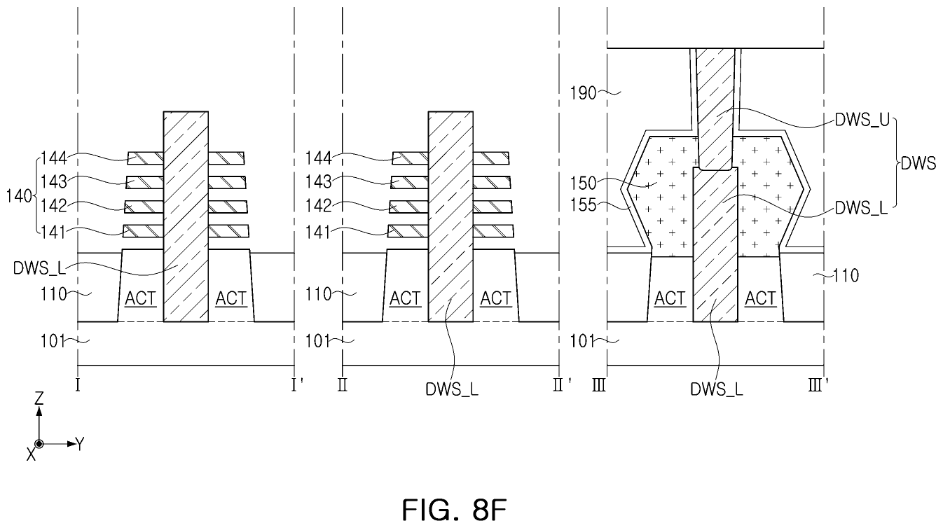

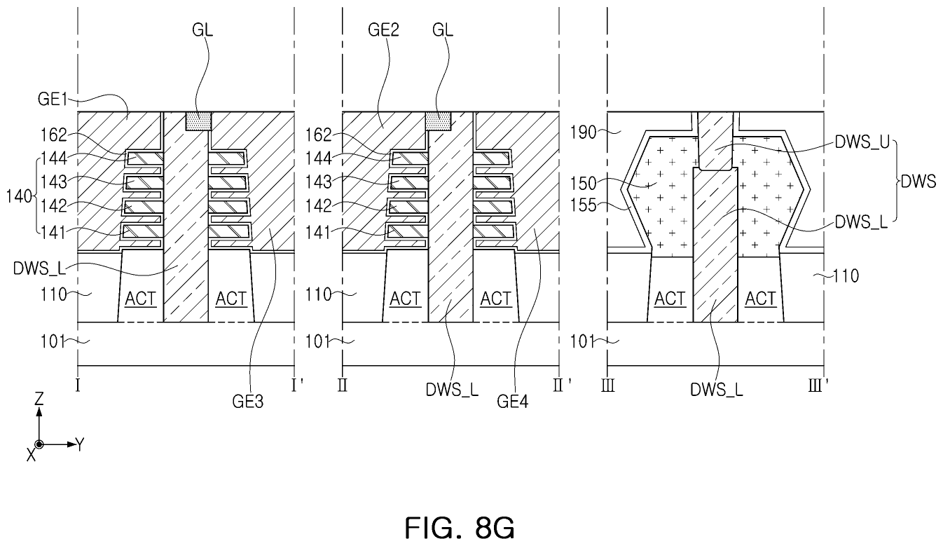

FIGS. 8A to 8G are views illustrating a process sequence illustrating a method of manufacturing a semiconductor device according to example embodiments. FIGS. 8A to 8G illustrate an embodiment of a method of manufacturing the semiconductor device of FIGS. 2A to 2C. FIGS. 8A to 8G illustrate a cross-section corresponding to FIG. 2A, respectively.

Referring to FIG. 8A, active structures may be formed on a substrate 101 in which sacrificial layers 120 and a first channel layer 141, a second channel layer 142, a third channel layer 143, and a fourth channel layer 144 are alternately stacked in the vertical direction, and a lower isolation structure DWS_L may be formed between the active structures.

The substrate 101 may include silicon (Si), germanium (Ge), or silicon germanium (SiGe). The substrate 101 may include a bulk wafer, an epitaxial layer, a silicon-on-insulator (SOI) layer, or a semiconductor-on-insulator (SeOI) layer.

The active structures may include the sacrificial layers 120 and the first channel layer 141, the second channel layer 142, the third channel layer 143, and the fourth channel layer 144, alternately stacked in the vertical direction, and may further include active regions ACT formed by removing a portion of the substrate 101 to protrude from the substrate 101. The active structures may be formed using a mask layer ML. The mask layer ML may be, for example, a hard mask layer. The active structures may be formed in a linear shape extending in one direction, for example, the X-direction, and may be formed to be spaced apart from each other in the Y-direction. The active regions ACT may further include impurities. The impurities may be implanted in a subsequent processing operation.

The sacrificial layers 120 may be layers to be replaced with gate dielectric layers 162 and the first gate electrode GE1, the second gate electrode GE2, the third gate electrode GE3, and the fourth gate electrode GE4 by a subsequent process, as illustrated in FIG. 2A. The sacrificial layers 120 may be formed of a material having etch selectivity with respect to the first channel layer 141, the second channel layer 142, the third channel layer 143, and the fourth channel layer 144, respectively. The first channel layer 141, the second channel layer 142, the third channel layer 143, and the fourth channel layer 144 may include a different material from the sacrificial layers 120. The sacrificial layers 120 and the first channel layer 141, the second channel layer 142, the third channel layer 143, and the fourth channel layer 144 may include a semiconductor material including at least one of, for example, silicon (Si), silicon germanium (SiGe), or germanium (Ge), but may include different materials, and may or may not include impurities. For example, the sacrificial layers 120 may include silicon germanium (SiGe), and the first channel layer 141, the second channel layer 142, the third channel layer 143, and the fourth channel layer 144 may include silicon (Si). The sacrificial layers 120 and the first channel layer 141, the second channel layer 142, the third channel layer 143, and the fourth channel layer 144 may be formed from the substrate 101 by performing an epitaxial growth process.

The lower isolation structure DWS_L may be formed by first conformally depositing an insulating material to cover the active structures, and then partially removing the insulating material by, for example, an etch-back process, to remain only between the active structures.

Referring to FIG. 8B, a device isolation layer 110 and sacrificial gate structures 200 may be formed.

The device isolation layer 110 may be formed by depositing an insulating material to fill a space between the active structures, and then removing a portion of a deposited insulating material from an upper portion to expose at least upper surfaces of the active regions ACT. In this operation, a level and a shape of an upper surface of the device isolation layer 110 may be variously changed.

The sacrificial gate structures 200 may be sacrificial structures formed in regions in which the gate dielectric layers 162, the first gate electrode GE1, the second gate electrode GE2, the third gate electrode GE3, the fourth gate electrode GE4, and the gate capping layers 167 are disposed on channel structures 140 through a subsequent process, as illustrated in FIG. 2A. The sacrificial gate structures 200 may have a linear shape extending in one direction while intersecting the active structures. The sacrificial gate structures 200 may extend, for example, in the Y-direction.

Each of the sacrificial gate structures 200 may include a first sacrificial gate layer 202, a second sacrificial gate layer 205, and a mask pattern layer 206, sequentially stacked in the vertical direction. The first sacrificial gate layer 202 and the second sacrificial gate layer 205 may be patterned using the mask pattern layer 206. The first sacrificial gate layer 202 and the second sacrificial gate layer 205 may be an insulating layer and a conductive layer, respectively, but are not limited thereto. In some embodiments, the first sacrificial gate layer 202 and the second sacrificial gate layer 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

On an outside of the sacrificial gate structures 200, the mask layer ML and a portion of the lower isolation structure DWS_L may be removed during formation of the sacrificial gate structures 200.

Referring to FIG. 8C, a portion of the active structures may be removed from the outside of the sacrificial gate structures 200.

The sacrificial layers 120 and the first channel layer 141, the second channel layer 142, the third channel layer 143, and the fourth channel layer 144, exposed from the sacrificial gate structures 200, may be removed. In this operation, after the sacrificial layers 120 and the first channel layer 141, the second channel layer 142, the third channel layer 143, and the fourth channel layer 144 are removed, exposed active regions ACT may also be partially recessed from upper surfaces, but are not limited thereto. By this operation, the first channel layer 141, the second channel layer 142, the third channel layer 143, and the fourth channel layer 144 may form channel structures 140 having a limited length in the X-direction.

Referring to FIG. 8D, an upper isolation structure DWS_U may be formed.

A separate mask layer may be formed on the entire structure being manufactured, and the same may be patterned to form an opening in a region corresponding to the upper isolation structure DWS_U of FIG. 2A. Then, the opening may be filled with an insulating material, and the mask layer may be removed, to form the upper isolation structure DWS_U.

Referring to FIG. 8E, source/drain regions 150 and insulating liner layers 155 may be formed.

The source/drain regions 150 may be formed by growing from the active regions ACT, for example, by a selective epitaxial process. The source/drain regions 150 may include impurities by in-situ doping. The insulating liner layers 155 may be conformally formed to cover surfaces of the source/drain regions 150, and may also be further formed on upper surfaces of the sacrificial gate structures 200.

In the embodiments of FIGS. 3A to 4B, before forming the source/drain regions 150 in this operation, the active regions ACT may be partially removed and then placeholder layers may be formed first. The placeholder layers may include a semiconductor material, and may have a different composition from the source/drain regions 150.

Referring to FIG. 8F, a first interlayer insulating layer 190 may be formed, and the sacrificial layers 120 and the sacrificial gate structure 200 may be removed.

The sacrificial layers 120 and the sacrificial gate structure 200 may be selectively removed with respect to the gate spacer layers 164, the first interlayer insulating layer 190, the source/drain regions 150, and the channel structures 140. For example, when the sacrificial layers 120 include silicon germanium (SiGe) and the channel structures 140 include silicon (Si), the sacrificial layers 120 may be selectively removed by performing a wet etching process. In this operation, the mask layer ML may also be removed.

Referring to FIG. 8G, the gate dielectric layers 162, the first gate electrode GE1, the second gate electrode GE2, the third gate electrode GE3, and the fourth gate electrode GE4 may be formed, and gate connection layers GL may be formed.

The gate dielectric layers 162 and the first gate electrode GE1, the second gate electrode GE2, the third gate electrode GE3, and the fourth gate electrode GE4 may be formed in regions in which the sacrificial layers 120 and the sacrificial gate structure 200 are removed. The gate dielectric layers 162 may be formed to conformally cover the inner surfaces of the regions. The first gate electrode GE1, the second gate electrode GE2, the third gate electrode GE3, and the fourth gate electrode GE4 may be formed to completely fill the regions, and then removed from an upper portion to a predetermined depth, together with the gate dielectric layers 162 and the gate spacer layers 164, by a planarization process or the like. In this operation, the upper isolation structure DWS_U may also be partially removed to reduce a height of the upper isolation structure DWS_U.

A gate connection layer GL may be formed by filling a conductive material after partially removing the isolation structure DWS and the gate dielectric layers 162 from upper surfaces thereof.

Next, referring to FIGS. 2A to 2C together, gate capping layers 167 may be formed on the first gate electrode GE1, the second gate electrode GE2, the third gate electrode GE3, and the fourth gate electrode GE4, the gate connection layer GL, and the upper isolation structure DWS_U, and source contact plugs CA, gate contact plugs CB, upper vias VA, and first interconnection lines M1 may be formed.

First, the source contact plugs CA penetrating the gate capping layers 167 and the first interlayer insulating layer 190 may be formed, and after forming a second interlayer insulating layer 192, the gate contact plugs CB penetrating the second interlayer insulating layer 192 and the gate capping layers 167 may be formed. The upper via VA may be formed on the source contact plugs CA, and the first interconnection lines M1 may be formed on the source contact plugs CA and the gate contact plugs CB. When there is an additional interconnection structure disposed on the first interconnection lines M1, the interconnection structure may be further formed in this operation. As a result, the semiconductor device 100 of FIGS. 1 to 2C may be manufactured.

In the embodiments of FIGS. 3A to 4B, after the above process is performed, the following processes may be further performed on a back surface of the substrate 101 to manufacture the semiconductor device 100a.

First, the substrate 101 and the active regions ACT may be removed, and a substrate insulating layer 103 may be formed. Next, a portion of the substrate insulating layer 103 and the placeholder layers may be removed, and then a conductive material may be deposited to form backside contact plugs BCA. Next, a back surface insulating layer 196 may be formed, and backside interconnection lines 180 connected to the backside contact plugs BCA may be formed.

By including a gate connection layer on an isolation structure, a semiconductor device having an improved degree of integration and electrical characteristics may be provided.

Various advantages and effects of the present disclosure are not limited to the above-described contents, and will be more easily understood in the process of explaining specific embodiments of the present disclosure.

While example embodiments have been illustrated and described above, it will be apparent to those skilled in the art that modifications and variations could be made without departing from the scope of the present disclosure as defined by the appended claims.

What is claimed is:

1. A semiconductor device, comprising:
a base structure extending in a first direction;
a plurality of gate electrodes including at least a first gate electrode and a second gate electrode disposed on the base structure and extending in a second direction, perpendicular to the first direction, the gate electrodes spaced apart from each other in the first direction and the second direction;
a plurality of channel layers disposed on the base structure, the plurality of channel layers spaced apart from each other in a third direction, perpendicular to the first direction and the second direction, the plurality of channel layers surrounded by the gate electrodes;
source/drain regions connected to the plurality of channel layers on opposite sides of the gate electrodes;
an isolation structure separating the gate electrodes, the plurality of channel layers, and the source/drain regions in the second direction, the isolation structure extending in the first direction; and
a gate connection layer electrically connecting the first gate electrode and the second gate electrode, the first gate electrode and the second gate electrode spaced apart from each other in a fourth direction intersecting the first direction and the second direction and being perpendicular to the third direction, the gate connection layer disposed on the isolation structure and contacting an upper surface of the isolation structure.

2. The semiconductor device of claim 1, wherein:
the gate connection layer includes a first side surface and a second side surface; and
the first side surface is in contact with the first gate electrode and the second side surface is in contact with the second gate electrode.

3. The semiconductor device of claim 1, wherein:
the gate connection layer includes a first lower surface;
each of the gate electrodes includes an upper surface and a second lower surface; and
the first lower surface is located on a level in the third direction lower than the upper surface and higher than the second lower surface.

4. The semiconductor device of claim 1, further comprising:
gate contact plugs disposed on the gate electrodes and electrically connected to the gate electrodes, wherein:
the gate connection layer includes a first upper surface;
each of the gate contact plugs includes a second upper surface; and
the first upper surface is located on a level in the third direction lower than the second upper surface.

5. The semiconductor device of claim 1, wherein:
the gate electrodes further include a third gate electrode and a fourth gate electrode spaced apart from the first gate electrode and the second gate electrode by the isolation structure in the second direction; and
the gate connection layer is spaced apart from the third gate electrode and the fourth gate electrode in the second direction.

6. The semiconductor device of claim 5, further comprising:
gate contact plugs, first interconnection lines, vias, and a second interconnection line, sequentially disposed on the gate electrodes in the third direction, wherein
the third gate electrode and the fourth gate electrode are electrically connected to each other through the gate contact plugs, the first interconnection lines, the vias, and the second interconnection line.

7. The semiconductor device of claim 1, wherein:
the gate connection layer includes a first upper surface;
each of the gate electrodes includes a second upper surface; and
the first upper surface is coplanar in the third direction with the second upper surface.

8. The semiconductor device of claim 7, wherein:
the gate connection layer has a first thickness in the third direction;
the gate electrodes have a second thickness on an uppermost channel layer of the plurality of channel layers in the third direction; and
the first thickness is smaller than the second thickness.

9. The semiconductor device of claim 1, wherein the gate connection layer includes a region extending in the fourth direction, or includes a first region extending in the first direction and a second region extending in the second direction.

10. The semiconductor device of claim 1, wherein:
the gate connection layer includes a side surface; and
a portion of the side surface is in contact with the isolation structure.

11. The semiconductor device of claim 1, wherein the isolation structure has a same height between the gate electrodes and between the source/drain regions.

12. The semiconductor device of claim 1, wherein the base structure includes a semiconductor material or an insulating material.

13. The semiconductor device of claim 1, further comprising:
a backside contact plug penetrating the base structure and connected to a lower portion of at least one of the source/drain regions.

14. A semiconductor device, comprising:
a first gate electrode and a second gate electrode spaced apart from each other in a first direction;
a third gate electrode and a fourth gate electrode spaced apart from each other in the first direction and spaced apart from the first gate electrode and the second gate electrode in a second direction, perpendicular to the first direction;
an isolation structure extending in the first direction between the first gate electrode and the third gate electrode and between the second gate electrode and the fourth gate electrode;
source/drain regions on opposite sides of the first gate electrode, the second gate electrode, the third gate electrode, and the fourth gate electrode in the first direction, the source/drain regions spaced apart from each other in the second direction by the isolation structure; and
a gate connection layer disposed on the isolation structure, the gate connection layer having side surfaces, contacting the second gate electrode and the third gate electrode through the side surfaces and electrically connecting the second gate electrode and the third gate electrode.

15. The semiconductor device of claim 14, wherein:
the first gate electrode is electrically separated from the third gate electrode by the isolation structure; and
the second gate electrode is electrically separated from the fourth gate electrode by the isolation structure.

16. The semiconductor device of claim 14, further comprising:
a gate contact plug disposed on the first gate electrode and the fourth gate electrode and on one of the first gate electrode or the second gate electrode.

17. The semiconductor device of claim 14, wherein an upper surface of the gate connection layer is covered with an insulating material.

18. The semiconductor device of claim 14, wherein the isolation structure includes:
a lower isolation structure between the first gate electrode and the third gate electrode and between the second gate electrode and the fourth gate electrode; and
an upper isolation structure extending between the source/drain regions on the lower isolation structure.

19. A semiconductor device, comprising:
gate structures spaced apart from each other in a first direction and a second direction, perpendicular to the first direction, each gate structure including a gate dielectric layer, a gate electrode, and a gate capping layer sequentially stacked in a third direction perpendicular to the first direction and the second direction;
a plurality of channel layers spaced apart from each other along the third direction and surrounded by the gate structures;
source/drain regions connected to the plurality of channel layers on opposite sides of the gate structure;
an isolation structure separating the gate structures, the plurality of channel layers, and the source/drain regions in the second direction, the isolation structure extending in the first direction; and
a gate connection layer disposed on the isolation structure and contacting the gate capping layer, the gate connection layer electrically connecting a first gate electrode and a second gate electrode spaced apart from each other in a fourth direction, intersecting the first direction and the second direction.

20. The semiconductor device of claim 19, wherein:
the gate connection layer includes a first upper surface;
the gate capping layer includes a second upper surface; and
the first upper surface is on a level in the third direction equal to or lower than the second upper surface.
